(19) United States
(12) Patent Application Publication
(10) Pub. No.: US 2006/0261456 A1
(43) Pub. Date: Nov. 23, 2006

(54) Micromodule, particularly for chip card

(75) Inventor: Francis Steffen, Saint Maximin (FR)

Correspondence Address: SEED INTELLECTUAL PROPERTY LAW GROUP PLLC, 701 FIFTH AVENUE, SUITE 6300, SEATTLE, WA, 98104-7092, US

(73) Assignee: STMicroelectronics S.A., Montrouge (FR)

(21) Appl. No.: 11/431,149

(22) Filed: May 9, 2006

(30) Foreign Application Priority Data
May 11, 2005 (FR) 05 04701

(51) Int. Cl. H01L 23/02

(52) U.S. Cl. 257/679

(57) ABSTRACT

An electronic micromodule, particularly for smart card, comprises an electrically insulating substrate, at least one conductive sheet in an electrically conductive material, which rear face is attached to a front face of the substrate, and a semi-conductor chip. The substrate comprises an opening forming a window of access to the rear face of the conductive sheet, the chip is arranged within the opening and is fixed onto the rear face of the conductive sheet, and at least one contact of the chip is electrically connected to the rear face of the conductive sheet by means of an electrically conductive connecting material. The electronic micromodule may embody chip cards, electronic badges and electronic tags.

### BACKGROUND OF THE INVENTION

1. Field of the Invention

The present invention relates to an electronic micromodule, particularly for chip card, comprising an electrically insulating substrate, at least a conductive sheet attached to the front face of the substrate and a semiconductor chip.

The present invention also relates to a method for manufacturing such an electronic micromodule.

2. Description of the Related Art

FIGS. 1A, 1B, 1C respectively represent a cross-sectional view, a top view and a bottom view of a classical electronic micromodule 1. The micromodule comprises an electrically insulating substrate 2, flexible or rigid. A conductive sheet 4 is fixed onto the front face of the substrate (FIG. 1B), and this sheet has been etched or cut so as to form conductive pads, here conductive pads from 4-1 to 4-8 of the ISO 7816 type. A silicon chip 5, which comprises a region of integrated circuit 6 and contacts 7, is fixed onto the rear face of the substrate (FIG. 1C). Contacts 7 are electrically linked to conductive pads 4 by means of metal wires 8 thanks to the “ultrasonic wire bonding” technique, the distal end of each wire being bond onto the rear face of conductive pads 4 through openings 9 made in substrate 2.

Such an electronic micromodule, embodied according to the “chip and wire” technique, is intended to be mounted onto a plastic card to form a chip card. It can also be used to manufacture electronic badges and other small portable objects comprising an integrated circuit.

However, such a micromodule has several drawbacks, considered as integral to its very structure. On the one hand, the ultrasonic wire bonding is a connection technique with a high cost of implementation and its automation is little compatible with the achievement of highly reliable electrical connections. On the other hand, the total thickness of the micromodule is not negligible since it is composed of the thickness of the silicon chip, the thickness of the substrate, the thickness of the conductive pads and the height of the loops formed by wirings.

### BRIEF SUMMARY OF THE INVENTION

One embodiment of the present invention provides a thin micromodule structure.

One embodiment of the present invention provides a micromodule structure with a low cost of implementation and having reliable electrical connections, easily adaptable to the automation of the production.

One embodiment of the present invention provides a method for manufacturing a micromodule without using the ultrasonic wire bonding technique for the connection of the contacts of the silicon chip to the conductive sheet.

One embodiment of the invention provides an electronic micromodule, notably for a chip card, comprising an electrically insulating substrate, at least one conductive sheet, in an electrically conductive material, which rear face is attached to the front face of the substrate, and a semiconductor chip comprising at least one contact, wherein the substrate comprises an opening forming a window of access to the rear face of the conductive sheet, the chip is arranged within the opening and is fixed onto the rear face of the conductive sheet, and at least one contact of the chip is electrically connected to the rear face of the conductive sheet by means of an electrically conductive connecting material.

According to one embodiment, the conductive sheet forms conductive pads, each having a region facing a contact of the chip and linked to it by means of the connecting material.

According to one embodiment, the conductive sheet forms an antenna coil comprising at least two regions, each facing a contact of the chip and linked to it by means of the connecting material.

According to one embodiment, the conductive sheet is made of copper.

According to one embodiment, the connecting material is a bump made of a melted material forming a weld.

According to one embodiment, the connecting material is a polymer filled with particles of an electrically conductive material.

According to one embodiment, the micromodule comprises a filling material occupying the opening between the chip and the rear face of the conductive sheet.

According to one embodiment, the thickness of the chip is less than the thickness of the substrate, and the chip does not protrude from the opening.

Another embodiment of the invention provides a portable electronic object comprising an electronic module.

A further embodiment of the invention provides a method for manufacturing an electronic module, particularly for chip card, comprising an electrically insulating substrate, at least one conductive sheet, made of an electrically conductive material, which rear face is attached to the front face of the substrate, and a semiconductor chip comprising at least one contact, method comprising the following steps of: forming an opening in the substrate, assembling the substrate and the conductive sheet so that the opening forms a window of access to the rear face of the conductive sheet, mounting the chip into the opening, and connecting at least one contact of the chip to the rear face of the conductive sheet by means of an electrically conductive connecting material.

According to one embodiment, the method comprises a step of etching or cutting the conductive sheet so as to form one or several conductive elements.

According to one embodiment, the method comprises a step of etching the conductive sheet, after assembling it onto the substrate, in a region of the conductive sheet where its rear face is in contact with the substrate, and a step of cutting the conductive sheet in a region of the conductive sheet where its rear face faces the opening made in the substrate.

According to one embodiment, the method comprises a step of etching or cutting the conductive sheet before mounting it onto the substrate, in order to form one or several conductive elements held to a frame by leads.

According to one embodiment, the conductive sheet is etched or cut so as to form conductive pads, electrically insulated from one another, each pad comprising a region facing a contact of the chip.

According to one embodiment, the conductive sheet is etched or cut so as to view an antenna coil that comprises at least two regions, each located in front of a contact of the chip.

According to one embodiment, the conductive sheet is made of copper.

According to one embodiment, the connecting material is a fusible material deposited as a bump.

According to one embodiment, the connecting material is a polymer material filled with particles of an electrically conductive material.

According to one embodiment, the method comprises a step of depositing a filling material between the front face of the chip and the rear face of the conductive sheet.

### BRIEF DESCRIPTION OF THE SEVERAL VIEWS OF THE DRAWINGS

These and other advantages and features of the present invention shall be presented in greater detail in the following description of two examples of embodiment of a micromodule according to the invention and of one example of a method for manufacturing the micromodule, in relation, but not limited to the following figures:

FIGS. 1A, 1B, 1C, described hereinbefore, respectively represent a cross-sectional view, a top view and a bottom view of a classical electronic micromodule for chip card,

FIGS. 2A, 2B, 2C respectively represent a cross-sectional view, a top view and a bottom view of a first example of embodiment of an electronic micromodule according to the invention,

FIGS. 3A to 3E represent steps of a manufacturing method of the micromodule according to the invention,

FIG. 4 is a top view of an etching mask used during the step shown in FIG. 3B,

FIG. 5 is a cross-sectional view of a punch used during the step described in FIG. 3D,

FIG. 6 is a top view representing a profile of conductive sheet and shows a variation of the method shown in FIGS. 3A to 3E,

FIG. 7 is a top view of a second example of embodiment of a micromodule according to the invention, and

FIG. 8 illustrates an embodiment of a portable electronic object.

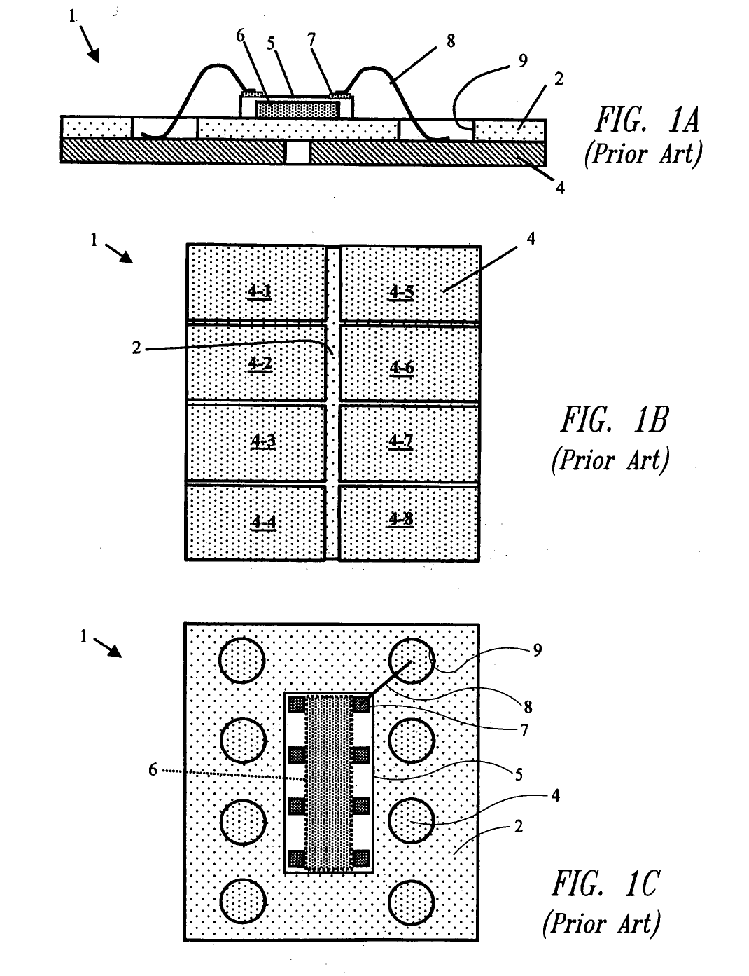

### DETAILED DESCRIPTION OF THE INVENTION

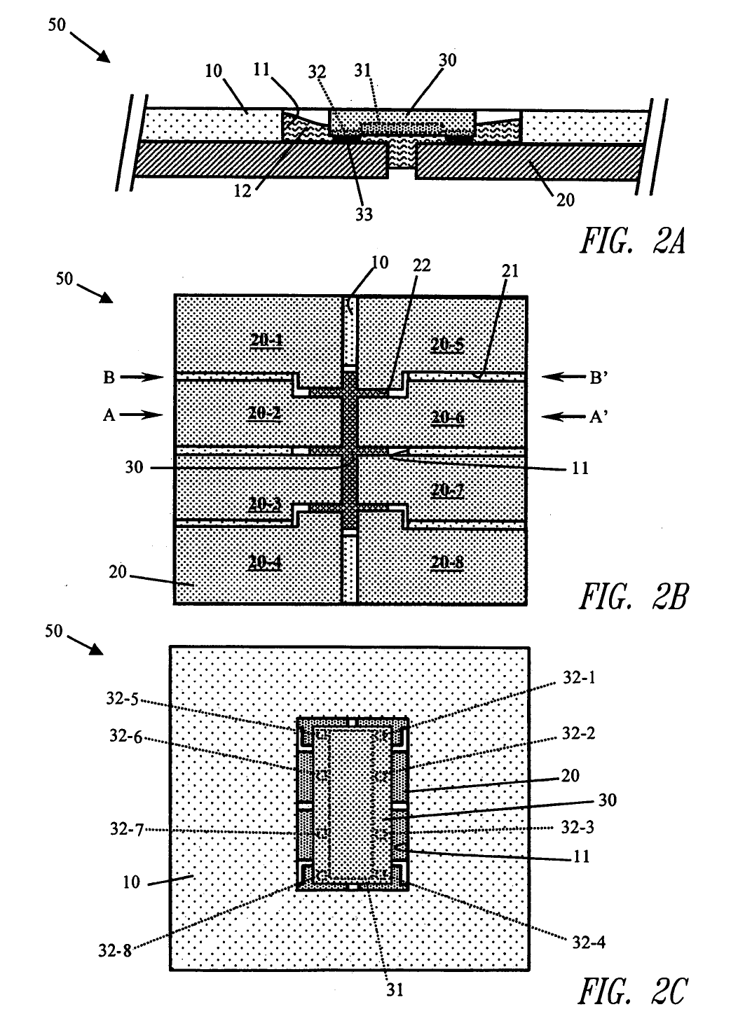

A first example of embodiment of an electronic micromodule 50 according to the invention is represented in FIGS. 2A, 2B, 2C respectively by a cross-sectional view, a top view and a bottom view, the cross-sectional view of FIG. 2A being a partial view according to an axis AA′ represented in FIG. 2B.

The micromodule 50 classically comprises three basic elements, namely, an electrically insulating substrate 10, a conductive sheet 20 made of an electrically conductive material, and a silicon chip 30.

The silicon chip 30 classically comprises, on its front face, a region of integrated circuit 31 and contacts 32 (metal-coated terminals), electrically linked to the integrated circuit region, here eight contacts 32-1 to 32-8 that can been seen in FIG. 2C. The conductive sheet 20 is attached to the front face of the substrate 10 and is cut or etched so as to form conductive elements which shapes depend on the target application. Here the conductive sheet 20 forms eight contact pads 20-1 to 20-8 of the ISO 7816 type, delimited by clearance zones or dividing zones 21, 22 without conductive material.

According to the invention, the substrate 10 comprises a central opening or window 11 in order to access the rear face of the conductive sheet 20. Dividing zones 21 stretch above the substrate 10 and dividing zones 22 stretch above the window 11.

Still according to the invention, the silicon chip is arranged within the cavity formed by the window 11, and is fixed on the rear face of the conductive sheet 20 according to the “flip chip” technique, that is, with its contacts 32 fixed on the sheet 20 by means of a conductive material, here forming bumps 33. For this purpose, the dividing zones 22 are arranged so that each contact pad 20-1 to 20-8 has a region facing a contact 32-1 to 32-8, and each contact 32-1 to 32-8 of the silicon chip is connected here to the corresponding conductive pad 20-1 to 20-8 by means of a conductive bump 33.

The conductive bumps 33 are, for example, in an eutectic alloy like tin-lead or tin-gold. A conductive polymer material, anisotropic or not, filled with metal particles, can also be used, the materials most commonly used for the connections of the flip-chip type being the Anisotropic Conductive Pastes or the Anisotropic Conductive Films (ACP or ACF). The Anisotropic Conductive Pastes or Films have the property of being electrically conductive in the direction contacts 32 to conductive pads 20 (vertical direction in FIG. 2A) and thus can be deposited into a uniform layer without causing a short circuit between contacts 32 (horizontal direction in FIG. 2A).

The cavity formed by the window 11 is totally or partially filled with an electrically insulating material 12, which totally or partially spreads under the silicon chip 30, between the front face of the silicon chip and the rear face of the conductive sheet.

The rigidity of the central region of the micromodule is thus ensured by the assembly of the silicon chip and the contact pads. As the silicon (and generally speaking all the types of semiconductors susceptible of being used to manufacture integrated circuits) has a Young's modulus clearly superior to the other materials forming the micromodule, the micromodule according to the invention is extremely resistant to distortion.

The substrate can be made of a semi-rigid material like epoxy or of a flexible material like the various compositions of polymers used in the electronics industry to manufacture substrates of the “flex” type.

The typical dimensions of the micromodule side are about ten millimetres, the dimensions of the conductive pads 20-1 to 20-8 being of approximately 2×3 mm for example. The substrate 10 is, for example, about 100 to 200 micrometers thick, plus the thickness of a layer of glue ensuring the assembly of the substrate 10 with the conductive sheet 20, typically some tens of micrometers. The conductive sheet 20 is, for example, a sheet of copper some tens of micrometers thick, typically of the order of 30 micrometers. The thickness of the bumps or of the conductive material in layer typically ranges from around ten to tens of micrometers, typically 20 micrometers for conductive bumps. After the backlap of its rear face, the thickness of the silicon chip 30 is preferably inferior to the thickness of the substrate 10, that is, of the order of 80 to 160 micrometers, so that the chip does not protrude from the opening formed by the window 11 and into which it is arranged.

Thus the invention provides means of manufacturing a thin micromodule, the thickness gained is at least equal to the thickness of the chip 30, not taking into account the height of the loops formed by the connecting wires in the micromodules of the type “chip and wires”.

Moreover, as the chip is arranged in the opening 11, the invention makes it possible, for a given thickness of the micromodule 50, to use a thicker silicon chip than the ones used with a classical micromodule. Indeed, in previous practices, in order to reduce the thickness of microdules, the thickness of silicon chips had to be drastically reduced, sometimes up to 50 micrometers, at the expense of the chips solidity, and resulting in low productivity because the silicon wafers were too thin before their cutting into individual chips.

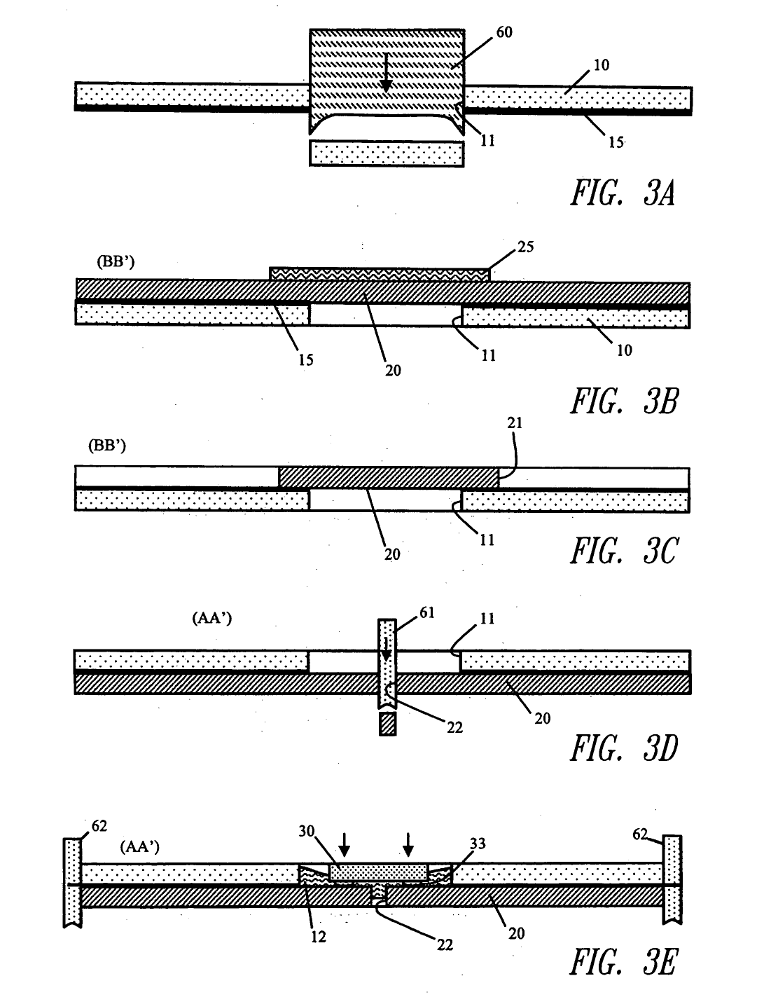

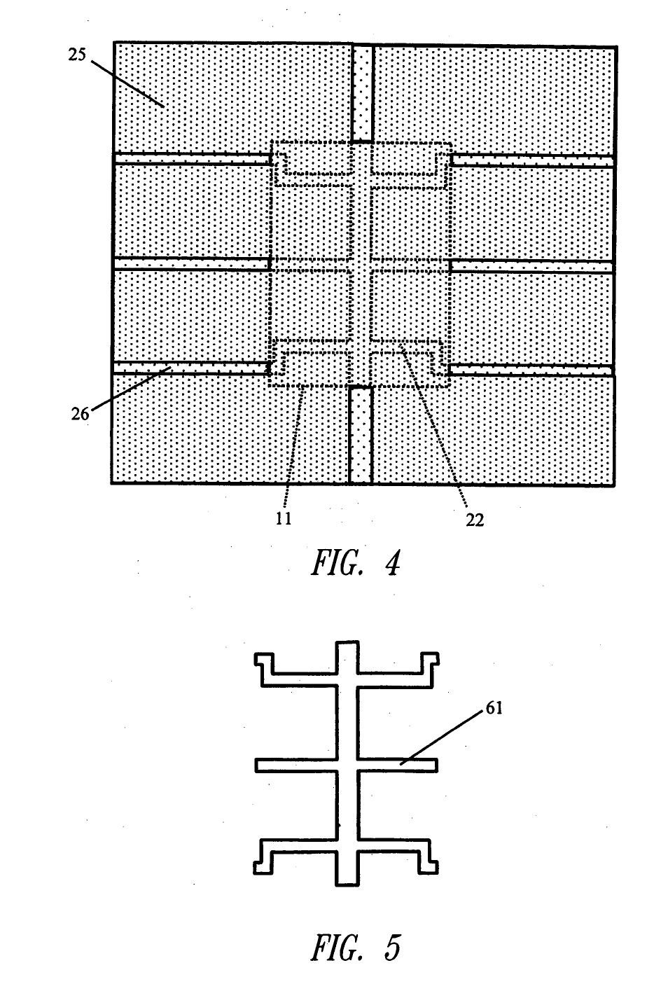

FIGS. 3A to 3E are cross-sectional views representing a method for manufacturing the micromodule 50, FIGS. 3B, 3C are cross-sectional views of the micromodule during the manufacturing process according to an axis BB′ represented in FIG. 2B, and FIGS. 3D, 3E being cross-sectional views of the micromodule according to the axis AA′ mentioned above.

Although these figures only represent one micromodule during the manufacturing process, the method is preferably implemented in order to manufacture several micromodules simultaneously and collectively.

During a step shown in FIG. 3A, the window 11 is cut in a sheet 10 of an electrically insulating material, intended to form the substrate. The window is made, for example, by stamping (simultaneous removal of a block of material) by means of a punch 60 with cutting edges of the same shape than the window 11 to be cut. Here the insulating sheet 10 is of the preglued type and it is overcoated with a layer of glue 15 some tens of micrometers thick.

During a step shown in FIG. 3B, the sheet or substrate 10 is assembled with a sheet 20 of conductive material, for example in copper, by means of the layer of glue. The front face of the sheet 20 is then covered up by an etching mask 25 and put in contact with an etching agent (abrasive solution, plasma, jet of abrasive particles, etc.). The profile of the etching mask 25 is represented in FIG. 4 in top view. The etching mask 25 has openings 26 facing the substrate 10, and has no openings in the region coinciding with the window 11 (marked by a dotted line). The openings 26 coincide (shape and arrangement) to the dividing zones 21 described hereinbefore (Cf. FIG. 2B).

Thus, as shown in FIG. 3C, after the etching and the removal of the etching mask 25, the conductive sheet 20 has the dividing zones 21 spreading above the substrate 10, but does not comprise the dividing zones 22 (indicated by a dotted line in FIG. 4) above the window 11.

Here, the dividing zones 22 intended to completely divide the contact pads 20-1 to 20-8 are made by stamping, by means of a punch 61 which cross-section is represented in FIG. 5. The operation is shown in FIG. 3D according to the transversal axis AA′, according to which the dividing zones 21 previously made do not appear. The punch 61 is applied on the rear face on the conductive sheet 20 in an up-and-down movement through the window 11 of the substrate 10.

During final steps shown in FIG. 3E, the silicon chip 30 is welded onto the conductive sheet 20 by means of the conductive bumps 33, which have been previously deposited onto the contacts of the chip. The “weld” is a hot bonding if an eutectic alloy is used or the bonding is carried out at ambient temperature if a conductive polymer is used. The rear face of the conductive sheet 20, in the region hosting the conductive bumps 33, can previously be submitted to a surface treatment ensuring the adhesion of the conductive material, for example a Copper deoxidization or the deposit of a thin adhesion layer, in Nickel, Zinc-nickel or Palladium for example. This treatment can be applied at any time before mounting the chip 30, for example before the steps of etching the conductive sheet 20 and assembling the sheet 20 and the substrate 10.

The filling material 12 is then injected by means of a syringe or an injector nozzle, preferably via the front face of the conductive sheet 20, that is, using the dividing zones 22 to inject the material 12, so that the material is well spread under the chip 30.

Optionally, and notably in the case of collective manufacturing of micromodules from big conductive sheets and insulating sheets, the perimeter of the micromodule (square, rectangular or any other desired shape) is cut by stamping by means of a cutting tool 62 of the corresponding shape.

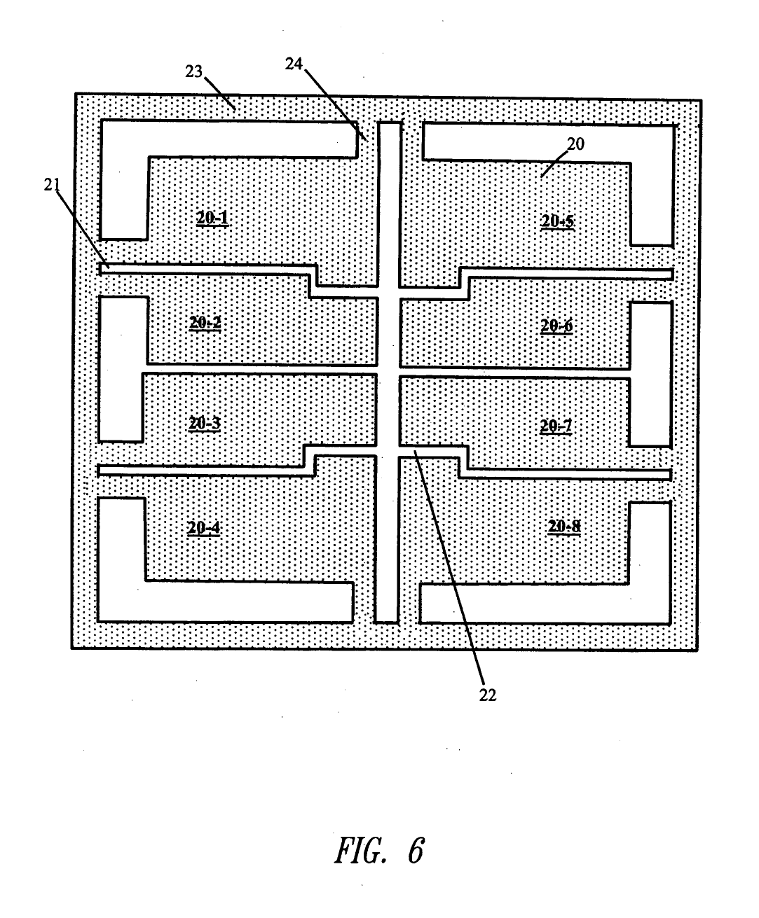

FIG. 6 shows a variation of the method wherein a technique called “lead frame” is applied. Here, the dividing zones 21, 22 are made in the conductive sheet 20 before assembling it to the substrate 10, so that the contact pads 20-1 to 20-8 are completely individualized. The contact pads are linked to a frame 23 by means of leads 24 which are cut during the final step of delimitating the outline of the micromodule by means of the above-mentioned tool 62.

As it will be clear to those skilled in the art, a micromodule according to the invention is susceptible of various variations of embodiment and applications.

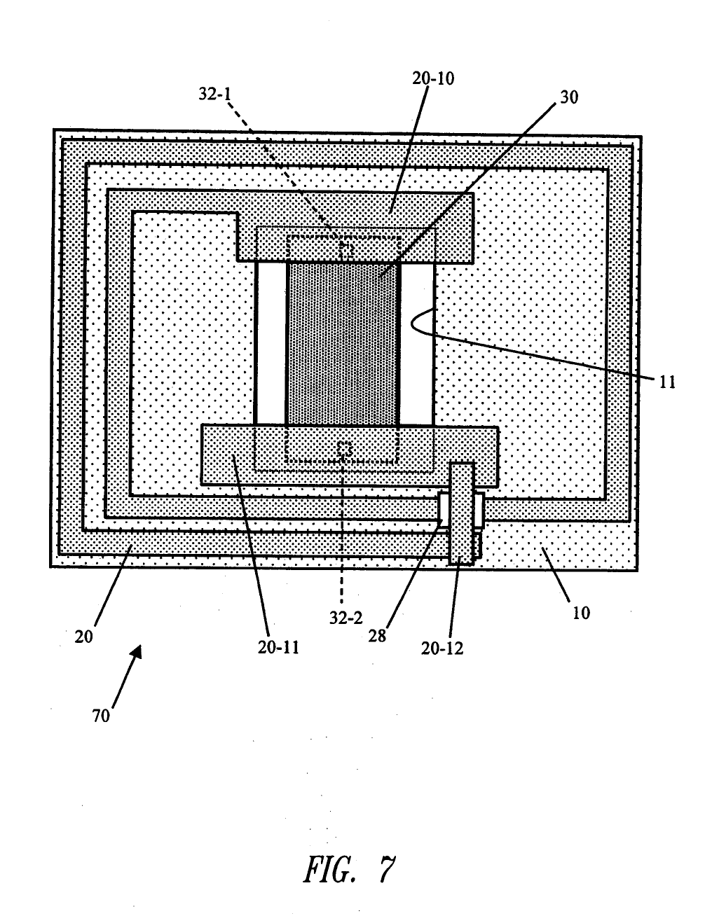

As an example, FIG. 7 is a top view of a micromodule 70 that is distinguished from the micromodule 50 by the conductive sheet 20 which was etched or cut (or etched and cut) so as to simultaneously form:

an antenna coil having an internal turn which is ending by a conductive pad 20-10, and

a pad 20-11 initially not electrically linked to the antenna coil.

The pads 20-10, 20-11 partially stretch above the window 11 made in the substrate 10. The silicon chip 30 has two contacts 32-1, 32-2 (indicated by a dotted line) which are soldered to the pads 20-10, 20-11 by means of the conductive bumps described hereinbefore. The pad 20-11 is then electrically linked to the end of an external turn of the antenna coil by means of a conductive strap 20-12. The strap 20-12 forms a conductive bridge above the internal turn from which it is electrically insulated thanks to a part 28 of insulating material locally deposited on the coil.

The micromodule 70 forms a contactless micromodule in the sense of the ISO 14443 norm or of the ISO 15693 norm and the antenna coil enables the integrated circuit embedded in the chip 30 to receive or send data by inductive coupling.

The micromodule 70 can be used to embody contactless chip cards, contactless electronic badges, or electronic tags, by being arranged on a portable support or embedded in a small portable support, notably a support in the shape of a card. Because it is thin, the micromodule can also been inserted into an object or a document, for example in a book for the management of libraries, in a passport, an ID card, a license to drive, etc.

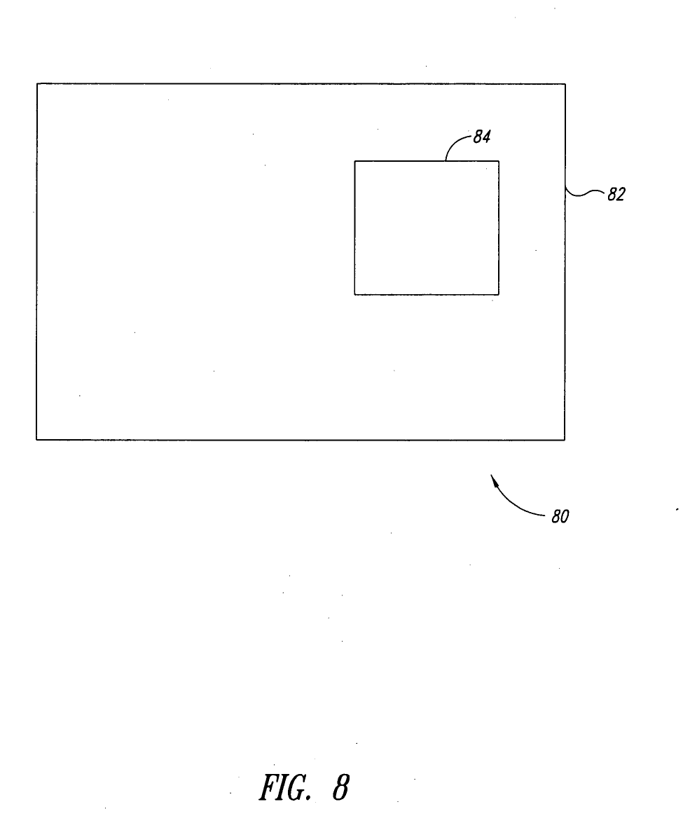

FIG. 8 illustrates an embodiment of a portable electronic object 80. The portable electronic object 80 includes a portable object 82 and a micromodule 84. In one embodiment, micromodule 84 is electronic micromodule 50 (FIG. 2A-2C). In another embodiment, micromodule 84 is electronic micromodule 70 (FIG. 7). The portable object 82 may be any portable object that is configured to support the micromodule 84.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. An electronic micromodule, particularly for chip cards, comprising:
a conductive sheet in an electrically conductive material, the conductive sheet including a rear face;
an electrically insulating substrate including a front face and an opening, the front face of the substrate being attached to the rear face of the conductive sheet and the opening forming a window of access to the rear face of the conductive sheet; and
a semiconductor chip including a contact, the chip being arranged within the opening and fixed onto the rear face of the conductive sheet and the contact being electrically connected to the rear face of the conductive sheet by a connector of an electrically conductive material.

2. A micromodule according to claim 1, wherein the contact is one of a plurality of contacts, the connector is one of a plurality of connectors, and the conductive sheet forms conductive pads each having a region facing and linked to a respective one of the plurality of contacts by a respective one of the plurality of connectors.

3. A micromodule according to claim 1, wherein the contact is one of a plurality of contacts, the connector is one of a plurality of connectors, and the conductive sheet forms an antenna coil comprising at least two regions each facing and linked to a respective one of the plurality of contacts by a respective one of the plurality of connectors.

4. A micromodule according to claim 1, wherein the conductive sheet is made of copper.

5. A micromodule according to claim 1, wherein the connecting material is a bump made of a melted material forming a weld.

6. A micromodule according to claim 1, wherein the connector is a polymer filled with electrically conductive particles.

7. A micromodule according to claim 1, further comprising a filling material occupying the opening between the chip and the rear face of the conductive sheet.

8. A micromodule according to claim 1, wherein a thickness of the chip is less than a thickness of the substrate, and the chip does not protrude from the opening.

9. A portable electronic object, comprising:
a portable object; and
an electronic micromodule connected to the portable object, the electronic micromodule including:
a conductive sheet in an electrically conductive material, the conductive sheet having a rear face,
an electrically insulating substrate having a front face and an opening, the front face of the substrate being attached to the rear face of the conductive sheet and the opening forming a window of access to the rear face of the conductive sheet, and
a semiconductor chip having a contact, the chip being arranged within the opening and fixed onto the rear face of the conductive sheet and the contact being electrically connected to the rear face of the conductive sheet by a connector of an electrically conductive material.

10. The portable electronic object of claim 9, wherein the portable object is an identification card.

11. The portable electronic object according to claim 9, wherein the contact is one of a plurality of contacts, the connector is one of a plurality of connectors, and the conductive sheet forms conductive pads each having a region facing and linked to a respective one of the plurality of contacts by a respective one of the plurality of connectors.

12. The portable electronic object according to claim 9, wherein the contact is one of a plurality of contacts, the connector is one of a plurality of connectors, and the conductive sheet forms an antenna coil comprising at least two regions each facing and linked to a respective one of the plurality of contacts by a respective one of the plurality of connectors.

13. The portable electronic object according to claim 9, wherein the conductive sheet is made of copper.

14. The portable electronic object according to claim 9, wherein the connecting material is a bump made of a melted material forming a weld.

15. The portable electronic object according to claim 9, wherein the connector is a polymer filled with electrically conductive particles.

16. The portable electronic object according to claim 9, further comprising a filling material occupying the opening between the chip and the rear face of the conductive sheet.

17. The portable electronic object according to claim 9, wherein a thickness of the chip is less than a thickness of the substrate, and the chip does not protrude from the opening.

18. A method for manufacturing an electronic module, particularly for chip card, the electronic module including an electrically insulating substrate having a front face, at least one conductive sheet made of an electrically conductive material and having a rear face, the rear face being attached to the front face of the substrate, and a semiconductor chip having at least one contact and a front face, the method comprising the following steps of:
forming an opening in the substrate;
assembling the substrate and the at least one conductive sheet, so that the opening forms a window of access to the rear face of the conductive sheet;
mounting the chip into the opening; and
connecting the at least one contact of the chip to the rear face of the conductive sheet by an electrically conductive connecting material.

19. A method according to claim 18, further comprising a step of etching or cutting the conductive sheet so as to form one or several conductive elements.

20. A method according to claim 19, wherein the step of etching or cutting comprises the steps of:
etching the conductive sheet after assembling it onto the substrate, in a region of the conductive sheet where the rear face of the conductive sheet is in contact with the substrate; and
cutting the conductive sheet in a region of the conductive sheet where therear face of the conductive sheet faces the opening formed in the substrate.

21. A method according to claim 19, wherein the step of etching or cutting comprises etching or cutting the conductive sheet, before mounting it onto the substrate, in order to form the one or several conductive elements held to a frame by leads.

22. A method according to claim 19, wherein the conductive sheet is etched or cut so as to form conductive pads electrically insulated from one another and each pad including a region facing a contact of the at least one contact of the chip.

23. A method according to claim 19, wherein the conductive sheet is etched or cut so as to form an antenna coil that includes at least two regions, each region facing a contact of the at least one contact of the chip.

24. A method according to claim 18, wherein the conductive sheet is made of copper.

25. A method according to claim 18, wherein the connecting material is a fusible material deposited as a bump.

26. A method according to claim 18, wherein the connecting material is a polymer material filled with electrically conductive particles.

27. A method according to claim 18, further comprising a step of depositing a filling material between the front face of the chip and the rear face of the conductive sheet.
